(19) United States
(12) Patent Application Publication
(10) Pub. No.: US 2026/0354214 A1
(43) Pub. Date: Nov. 5, 2026

(54) LEAD FRAME BASED ANTENNA

(71) Applicant: TEXAS INSTRUMENTS INCORPORATED, Dallas, TX (US)

(72) Inventors: Harshpreet Singh Phull BAKSHI, Dallas, TX (US); Satyendra S. CHAUHAN, Murphy (TX); Rajen Manicon MURUGAN, Dallas, TX (US)

(21) Appl. No.: 19/195,482

(22) Filed: Apr. 30, 2025

(51) Int. Cl. H10W 70/40; H01Q 1/22; H01Q 9/16; H10W 70/04; H10W 74/01; H10W 74/10

(52) U.S. Cl. CPC H10W 70/415; H01Q 1/2283; H01Q 9/16; H10W 70/048; H10W 70/481; H10W 74/01; H10W 74/111

(57) ABSTRACT

In examples, a semiconductor package includes a semiconductor die and a portion of a lead frame, comprising conductive terminals coupled to the semiconductor die and a first segment having first, second, and third members and a second segment having fourth, fifth, and sixth members. The first and fourth members are coupled to the semiconductor die. The second and fifth members extend from the first and fourth members, respectively, toward a center of the semiconductor die. The second and fifth members extend parallel to each other. The third and sixth members extend from the second and fifth members, respectively, in opposing directions perpendicular to the second and fifth members. A mold compound contacts the semiconductor die and the portion of the lead frame.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such integrated circuits on a wafer is called fabrication. After wafer fabrication, the wafer is cut into multiple pieces, called semiconductor dies, with each die containing one or more of the integrated circuits. The cutting, or sawing, of the wafer into individual dies is called singulation. An individual die may then be attached to a substrate or die attach pad. The resulting structure is subsequently covered with a mold compound to produce a package.

### SUMMARY

In examples, a semiconductor package includes a semiconductor die and a portion of a lead frame, comprising conductive terminals coupled to the semiconductor die and a first segment having first, second, and third members and a second segment having fourth, fifth, and sixth members. The first and fourth members are coupled to the semiconductor die. The second and fifth members extend from the first and fourth members, respectively, toward a center of the semiconductor die. The second and fifth members extend parallel to each other. The third and sixth members extend from the second and fifth members, respectively, in opposing directions perpendicular to the second and fifth members. A mold compound contacts the semiconductor die and the portion of the lead frame.

In examples, a method for manufacturing a semiconductor package includes coupling first and second semiconductor dies to a lead frame strip having first and second lead frames, the first lead frame including a first set of conductive terminals attached to a dam bar, a first member attached to the dam bar and extending lengthwise along the lead frame strip, and a second member attached to the dam bar and extending lengthwise along the lead frame strip in a direction opposite that of the first member, the second lead frame including a second set of conductive terminals attached to the dam bar, the second member, and a third member attached to the dam bar and extending lengthwise along the lead frame strip, the second member shared by the first and second lead frames, where the first semiconductor die is coupled to the first set of conductive terminals, the first member, and the second member, and where the second semiconductor die is coupled to the second set of conductive terminals, the second member, and the third member. The method includes covering the first and second semiconductor dies and the lead frame strip with a mold compound. The method includes sawing the mold compound, where the semiconductor package includes the first semiconductor die, the first set of conductive terminals, the first member, and a portion of the second member.

### BRIEF DESCRIPTION OF THE DRAWINGS

FIG. 1 is a flow diagram of a method for manufacturing a semiconductor package having a lead frame based antenna, in accordance with various examples.

FIGS. 2A-2G are a process flow showing the manufacture of a semiconductor package having a lead frame based antenna, in accordance with various examples.

FIGS. 3A-3F are perspective, top, profile, profile, profile, and profile views, respectively, of a semiconductor package having a lead frame based dipole antenna, in accordance with various examples.

FIGS. 4A-4F are perspective, top, profile, profile, profile, and profile views, respectively, of a semiconductor package having a lead frame based monopole antenna, in accordance with various examples.

FIGS. 5A-5F are perspective, top, profile, profile, profile, and profile views, respectively, of a semiconductor package having a lead frame based loop antenna, in accordance with various examples.

FIG. 6 is a graph depicting the performance of a lead frame based antenna, in accordance with various examples.

FIGS. 7 and 8 are schematic diagrams showing the radiation patterns produced by a lead frame based antenna, in accordance with various examples.

FIG. 9 is a block diagram of an electronic device including a semiconductor package having a lead frame based antenna, in accordance with various examples.

### DETAILED DESCRIPTION

Antennas are transducers that convert between electrical signals and electromagnetic waves for transmission and reception, enabling wireless communication across defined frequency bands. Antennas operate by radiating or capturing radio frequency energy through conductive elements that resonate at specific wavelengths. In electronic systems and devices, antennas are typically attached to printed circuit boards (PCBs) or occupy regions external to PCBs, with both possibilities representing significant space and manufacturing cost investments.

This description presents various examples of a semiconductor package having a lead frame based antenna. Specifically, the semiconductor packages described herein include portions of lead frames that form antennas of various types (e.g., dipole, monopole, loop). Because such an antenna is part of a portion of a lead frame within a semiconductor package, no additional manufacturing steps are needed to form the antenna during semiconductor package back-end assembly. Thus, manufacturing complexities and costs are mitigated. Furthermore, because the antennas are included within the semiconductor package instead of outside of the semiconductor package, space is conserved. More specifically, because the antenna is part of a portion of a lead frame and thus is in the same horizontal plane as the remainder of the lead frame, the antenna can be included as part of the semiconductor package without increasing the thickness of the semiconductor package. Further still, at least some of the examples described herein are low-cost packages (e.g., small outline transistor (SOT) packages). Including a lead frame based antenna within a low-cost semiconductor package, such as a SOT package, enables manufacturers to deliver enhanced functionality without significant production or end-user costs.

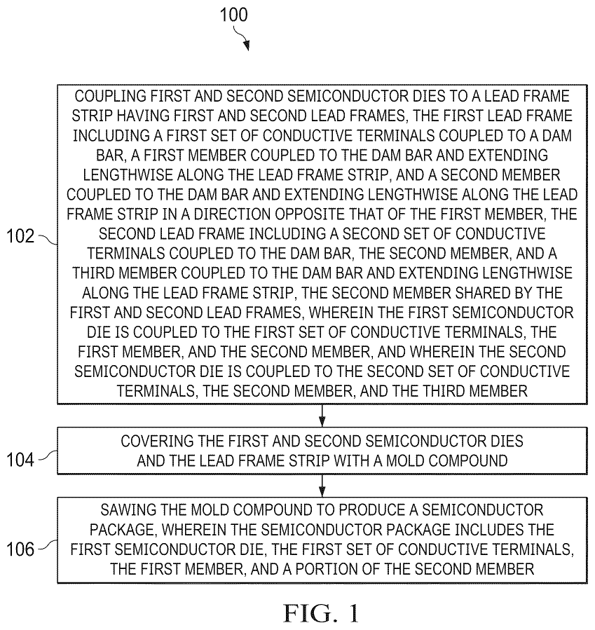

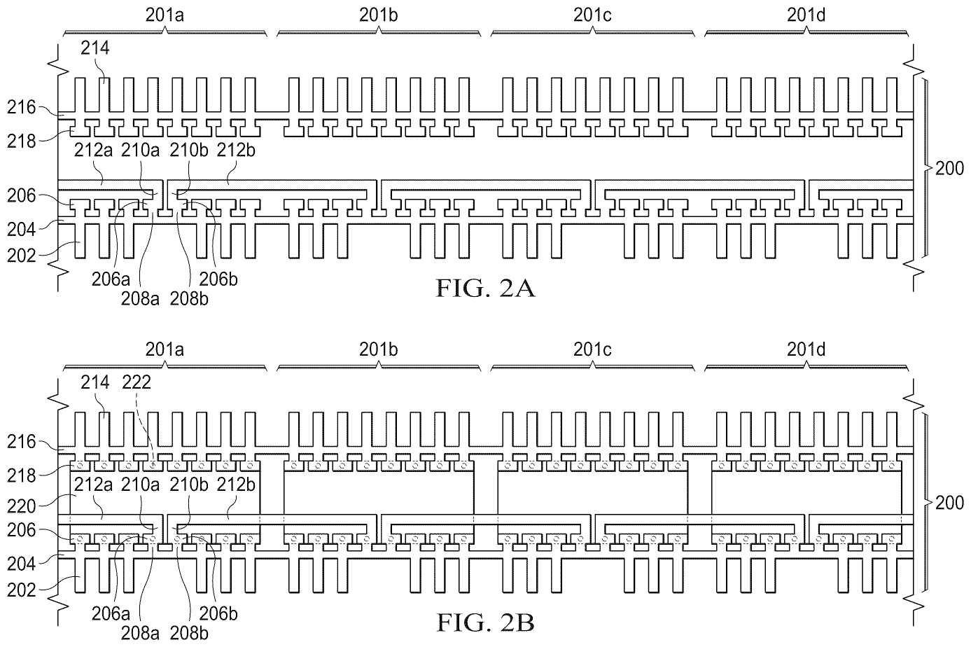

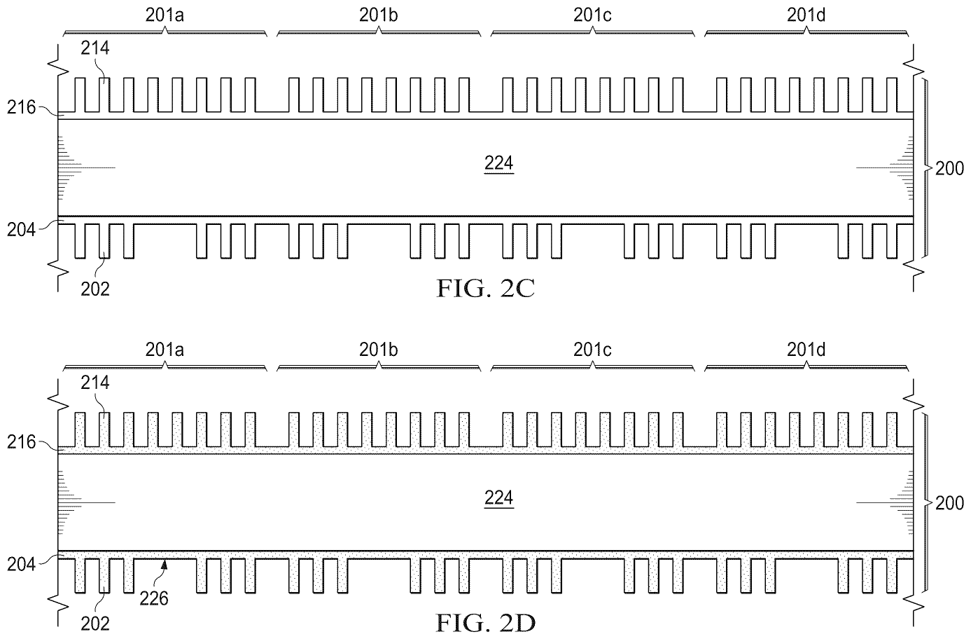

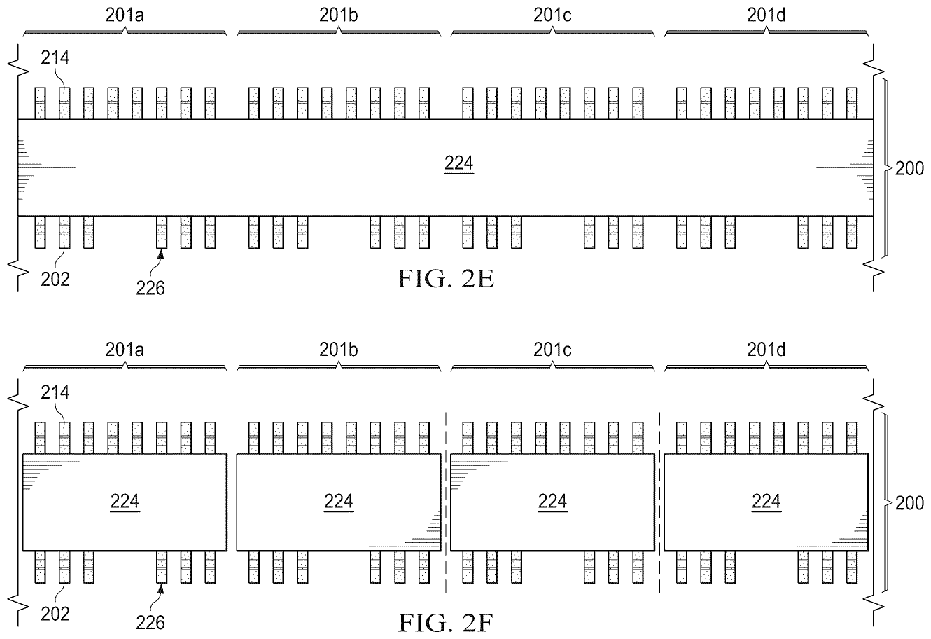

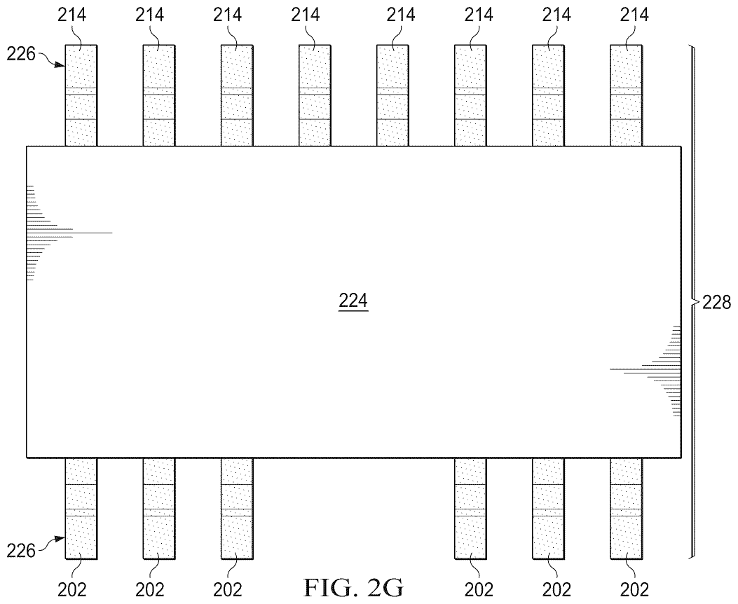

FIG. 1 is a flow diagram of a method 100 for manufacturing a semiconductor package having a lead frame based antenna, in accordance with various examples. FIGS. 2A-2G are a process flow showing the manufacture of a semiconductor package having a lead frame based antenna, in accordance with various examples. Accordingly, FIGS. 1 and 2A-2G are described in parallel.

The method 100 includes coupling first and second semiconductor dies to a lead frame strip having first and second lead frames (102). The first lead frame includes a first set of conductive terminals attached to a dam bar, a first member attached to the dam bar and extending lengthwise along the lead frame strip, and a second member attached to the dam bar and extending lengthwise along the lead frame strip in a direction opposite that of the first member (102). The second lead frame includes a second set of conductive terminals attached to the dam bar, the second member, and a third member attached to the dam bar and extending lengthwise along the lead frame strip (102). The second member is shared by the first and second lead frames (102). The first semiconductor die is coupled to the first set of conductive terminals, the first member, and the second member, and the second semiconductor die is coupled to the second set of conductive terminals, the second member, and the third member (102).

FIG. 2A is a top-down view of a lead frame strip 200. The lead frame strip 200 may be manufactured by any suitable technique, such as stamping, chemical etching, or laser cutting. The lead frame strip 200 may include any number of lead frame portions (also referred to herein as portions of a lead frame), each of which may subsequently be included in a different semiconductor package, as described below. Although the lead frame strip 200 may include any number of such lead frame portions, the example of FIG. 2A shows four such lead frame portions 201a, 201b, 201c, and 201d, which may collectively be referred to herein as lead frame portions 201. Each lead frame portion 201a-201d includes conductive terminals 202 (e.g., leads), a dam bar 204 attached to the conductive terminals 202, and members 206 (e.g., members 206a and 206b) attached to the conductive terminals 202. A member 208a (e.g., a tie bar) is attached to the member 206a and to the dam bar 204, and a member 208b (e.g., a tie bar) is attached to the member 206b and to the dam bar 204. In some examples, each of the members 208a and 208b is narrower than each of the conductive terminals 202. A member 210a is attached to the member 206a, and a member 210b is attached to the member 206b. A member 212a is attached to the member 210a, and a member 212b is attached to the member 210b. Within the context of the lead frame portion 201a, the members 212a and 212b are said to be extending in opposite directions from each other. Similarly, in each of the lead frame portions 201b-201d, the members 212a and 212b are said to be extending in opposite directions from each other. Collectively, the members 206a, 210a, and 212a may be referred to herein as a first segment, and the members 206b, 210b, and 212b may be referred to herein as a second segment. Each lead frame portion 201a-201d also includes conductive terminals 214, a dam bar 216 attached to the conductive terminals 214, and members 218 attached to the conductive terminals 214.

Some of the components in each of the lead frame portions 201a-201d are shared with one or more of the other lead frame portions 201a-201d. For example, the member 212b in the lead frame portion 201a is attached to the member 212a in the immediately adjacent lead frame portion 201b. Similarly, the member 212b in the lead frame portion 201b is attached to the member 212a in the immediately adjacent lead frame portion 201c, and the member 212b in the lead frame portion 201c is attached to the member 212a in the immediately adjacent lead frame portion 201d. Likewise, each of the dam bars 204 and 216 may extend through all of the lead frame portions 201a-201d, as shown in FIG. 2A.

Because the lead frame strip 200 may be produced by a subtractive process, such as stamping, chemical etch, or laser cutting process, the lead frame strip 200 is a monolithic structure. Accordingly, the individual components of the lead frame strip 200 are not “attached” to each other like separate components are connected to each other by an adhesive or solder. Rather, when used to describe the structure of the lead frame strip 200, the term “attached” means that a component A and a component B are different parts of a continuous, monolithic whole.

In examples, the conductive terminals 202 in the lead frame portion 201a extend parallel to each other and away from a center of the lead frame portion 201a. The same is true for the conductive terminals 202 in the lead frame portions 201b-201d with reference to the centers of the lead frame portions 201b-201d, respectively. (The centers of the lead frame portions 201a-201d are considered equivalent to the centers of the semiconductor packages that will subsequently be formed using those respective lead frame portions 201a-201d.) The dam bar 204 extends perpendicular to the conductive terminals 202 and along a length of the lead frame strip 200. The members 206 extend parallel to the dam bar 204. The members 208a and 208b extend parallel to the conductive terminals 202. The members 210a and 210b in the lead frame portion 201a extend toward the center of the lead frame portion 201a, parallel to each other, and parallel to the conductive terminals 202. The members 212a and 212b extend parallel to the dam bar 204, perpendicular to the conductive terminals 202, perpendicular to the members 210a, 210b, and along the length of the lead frame strip 200.

FIG. 2B is a top-down view of the structure of FIG. 2A, except that semiconductor dies 220 are coupled to the lead frame portions 201a-201d. Each of the semiconductor dies 220 includes a device side including an integrated circuit and a non-device side opposite the device side. In the top-down view of FIG. 2B, the device sides of the semiconductor dies 220 are visible, and the non-device sides of the semiconductor dies 220 are not visible because the non-device sides are facing away. In examples, each of the semiconductor dies 220 is coupled to multiple of the members 206 and 218 by solder bumps 222. For example, a different solder bump 222 may couple each of the members 206 to the device side of one of the semiconductor dies 220, and a different solder bump 222 may couple each of the members 218 to the device side of that semiconductor die 220. By coupling a semiconductor die 220 to a member 206 and/or to a member 218, that semiconductor die 220 is indirectly coupled to the various other component(s) that are coupled to that member 206 and/or to that member 218.

The member 212a in the lead frame portion 201a may be considered the “first member” in step 102 of the method 100. The member 212b in the lead frame portion 201a, along with the member 212a in the lead frame portion 201b, may be considered the “second member” in step 102 of the method 100. The member 212b in the lead frame portion 201b may be considered the “third member” in step 102 of the method 100. When one of the semiconductor dies 220 is coupled to the lead frame portion 201a, that semiconductor die 220 is coupled to the first and second members (e.g., the members 212a, 212b in the lead frame portion 201a) by way of the members 206a, 206b, respectively. That semiconductor die 220 is also coupled to the conductive terminals 202 of the lead frame portion 201a by way of the remaining members 206 in that lead frame portion 201a. A similar description applies for the remaining semiconductor dies 220 that are coupled to the remaining lead frame portions 201b-201d.

The method 100 may include covering the first and second semiconductor dies and the lead frame strip with a mold compound (104). FIG. 2C is a top-down view of the structure of FIG. 2B, except that a mold compound 224 covers the lead frame strip 200 and the semiconductor dies 220 coupled to the lead frame strip 200. The mold compound 224 may be applied by positioning the structure of FIG. 2B in a mold chase and injecting the mold compound 224 to cover the lead frame strip 200 and the semiconductor dies 220.

In some examples, some metal components may remain exposed after application of the mold compound 224 to the lead frame strip 200. For instance, because the dam bars 204 and 216 limit the flow of the mold compound 224, portions of the dam bars 204 and 216 remain exposed after the mold compound 224 is applied to the lead frame strip 200. Similarly, portions of the conductive terminals 202, 214 remain exposed after the mold compound 224 is applied to the lead frame strip 200. Because the lead frame strip 200 may comprise a metal or alloy vulnerable to oxidation and/or corrosion (e.g., copper), these exposed portions of the lead frame strip 200 may be susceptible to oxidation and/or corrosion. Accordingly, these exposed portions of the lead frame strip 200 may be plated (covered by a metal coating, e.g., electroplated) after the mold compound 224 has been applied, thereby covering these portions of the lead frame strip 200 with a metal or metal alloy that can protect from oxidation and/or corrosion. Such plating also may facilitate solderability. Example plating materials may include one or more of nickel, palladium, gold, tin, and silver. FIG. 2D is a top-down view of the structure of FIG. 2C, except that a plated layer 226 covers the exposed portions of the lead frame strip 200.

FIG. 2E is a top-down view of the structure of FIG. 2D, except that the dam bars 204 and 216 are trimmed (removed), and the conductive terminals 202 and 214 are formed (bent) to have a gullwing shape. In some examples, after forming (bending) the conductive terminals 202 and 214, all portions of the lead frame strip 200 are coplanar (e.g., in a horizontal plane) except for the portions of the conductive terminals 202 and 214 that have been bent, as well as the portions of the conductive terminals 202 and 214 distal to the portions of the conductive terminals 202 and 214 that have been bent. The trimming process is facilitated because the dam bars 204 and 216 are not covered by the mold compound 224. Trimming the dam bars 204 and 216 after the aforementioned plating process may cause the underlying lead frame strip metal (e.g., copper) to be exposed at the areas where the dam bars 204 and 216 join with components of the lead frame strip 200 that are not removed, such as the intersections of the dam bars 204 and 216 with the conductive terminals 202 and 214. Thus, after removal of the dam bars 204 and 216, the areas of the conductive terminals 202 and 214 formerly joined with the dam bars 204 and 216 may include exposed copper. Similarly, the distal ends of the members 208a and 208b may include exposed copper. Accordingly, in some examples, the dam bars 204 and 216 may be trimmed before the plating process is performed, so that the subsequent plating process covers metal areas that would otherwise remain vulnerable to corrosion/oxidation.

The method 100 may include sawing the mold compound to produce a semiconductor package (106). The resulting semiconductor package includes the first semiconductor die, the first set of conductive terminals, the first member, and a portion of the second member (106). FIG. 2F is a top-down view of the structure of FIG. 2E, except that the structure of FIG. 2E has been sawn (e.g., using a mechanical or laser saw) to produce individual semiconductor packages 228, an example of which is shown in the top-down view of FIG. 2G. The semiconductor package 228 includes one of the semiconductor dies 220, a set of conductive terminals 202, a member 212a, and a member 212b. The member 212b may be considered to be “a portion of the second member” (106) because, prior to the singulation step 106, the member 212b may have been attached to the member 212a of an immediately adjacent lead frame portion 201.

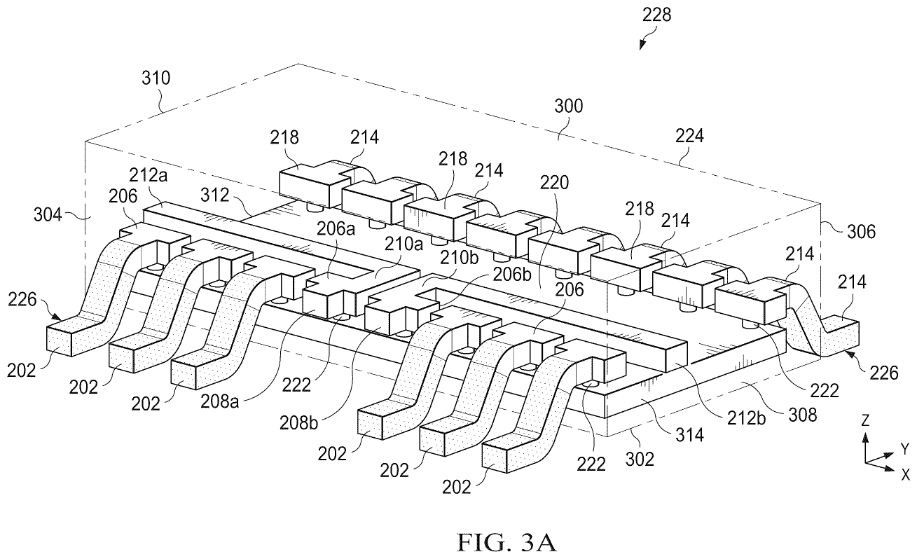

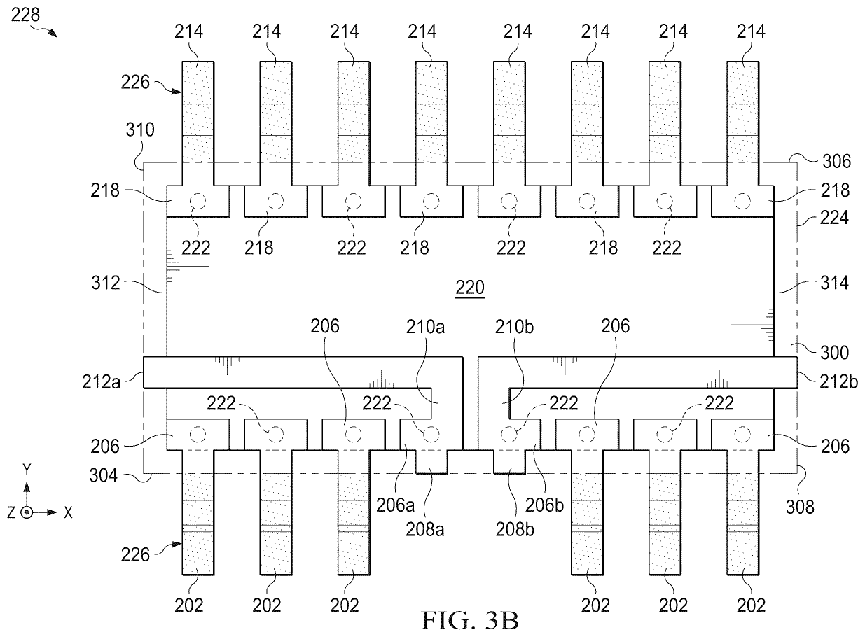

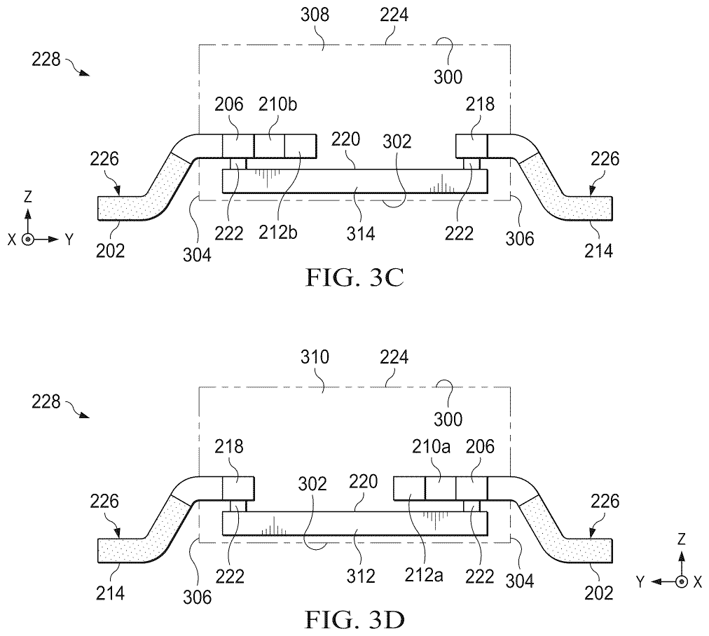

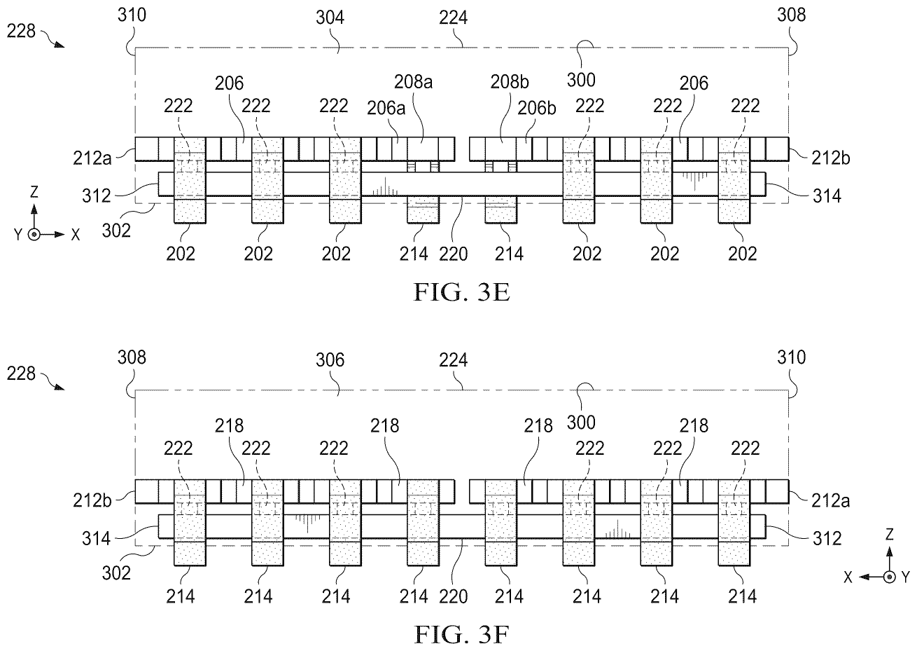

FIGS. 3A-3F are perspective, top, profile, profile, profile, and profile views, respectively, of a semiconductor package having a lead frame based dipole antenna, in accordance with various examples. More specifically, FIGS. 3A-3F depict the completed semiconductor package 228 as manufactured according to the method 100 and the process flow of FIGS. 2A-2G. The semiconductor package 228, and more specifically, the mold compound 224, includes a top surface 300, a bottom surface 302, and four lateral surfaces 304, 306, 308, and 310. The conductive terminals 202 and 214 extend through the surfaces 304 and 306 of the mold compound 224. In examples, the mold compound 224 fully covers the semiconductor die 220. The distal ends of members 208a and 208b may be exposed on the surface 304 of the mold compound 224. A distal end of the member 212a may be exposed on the surface 310 of the mold compound 224. A distal end of the member 212b, which is opposite the distal end of the member 212a, may be exposed on the surface 308 of the mold compound 224. In examples, the distal end of the member 212a may extend past a vertical plane defined by an edge 312 of the semiconductor die 220. Similarly, in examples, the distal end of the member 212b may extend past a vertical plane defined by an edge 314 of the semiconductor die 220. The members 212a and 212b are coupled to the semiconductor die 220 by solder bumps 222, which may cause the members 212a and 212b to be separated from the semiconductor die 220, meaning that the members 212a and 212b may not directly contact the semiconductor die 220. The members 212a and 212b may collectively operate as a dipole antenna. An integrated circuit on the semiconductor die 220 may operate the dipole antenna by transmitting signals to and receiving signals from the dipole antenna.

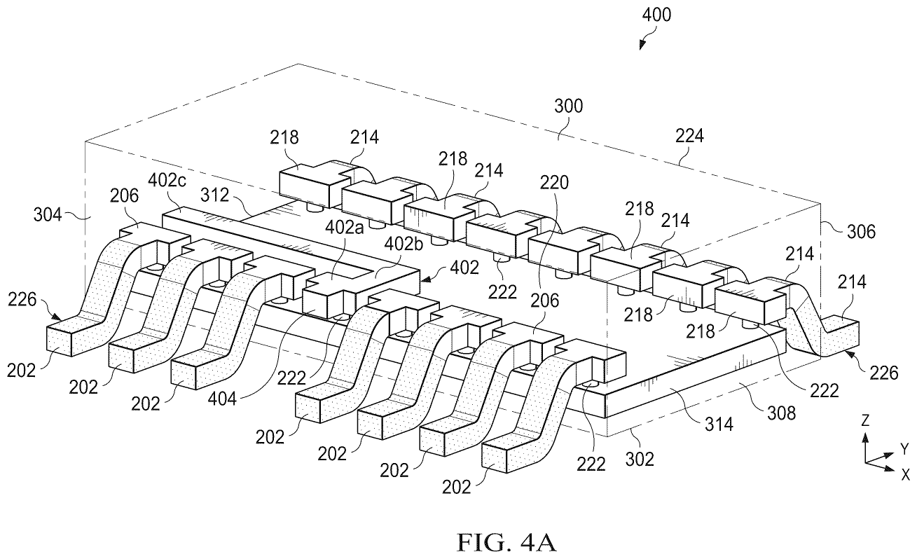

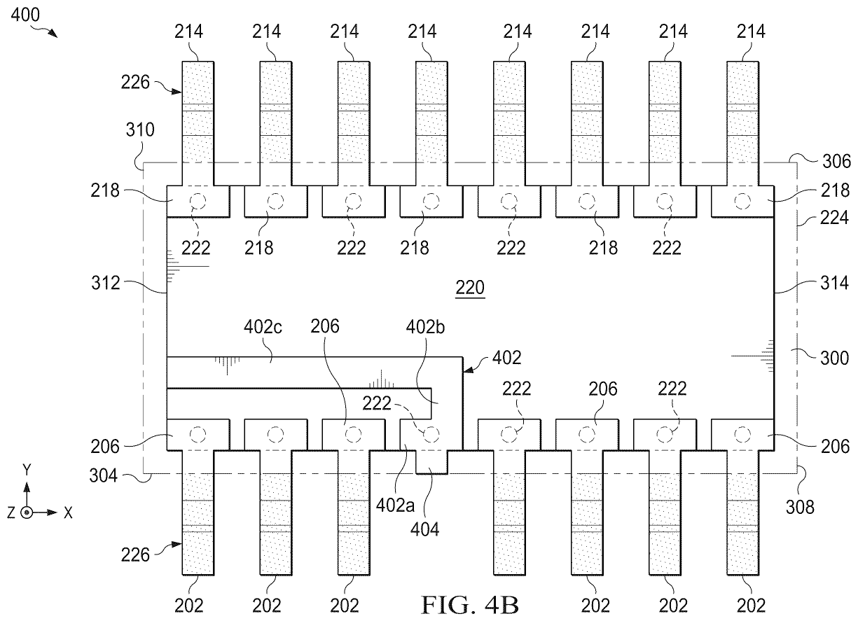

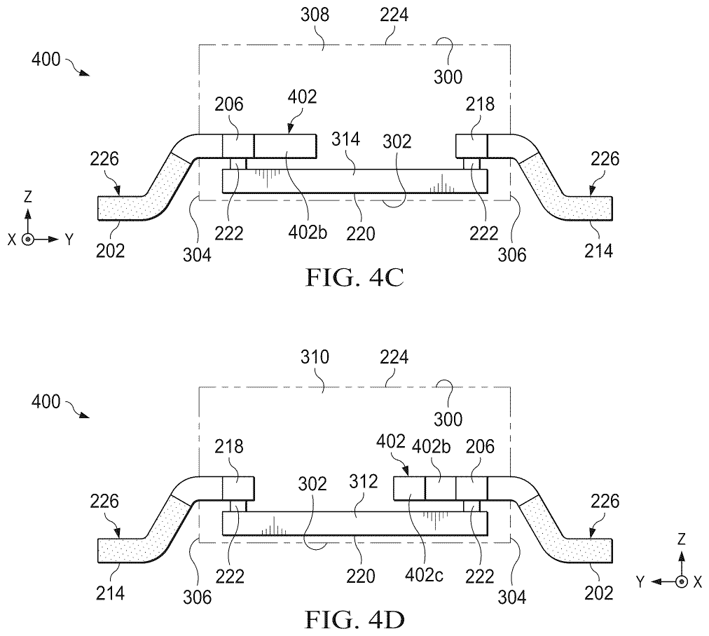

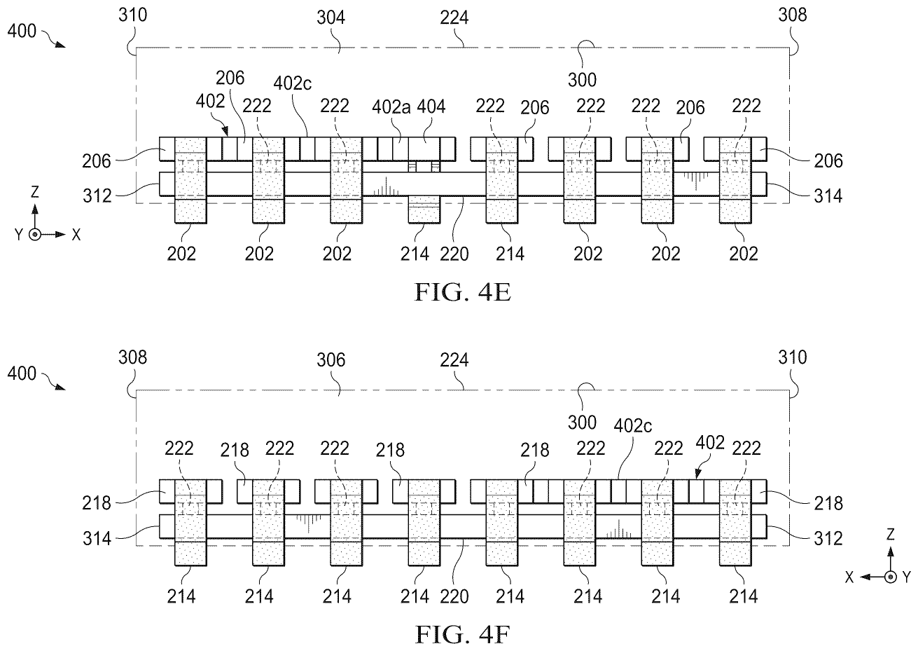

The scope of this disclosure is not limited to semiconductor packages with dipole antennas. Other types of antennas, such as monopole antennas, are contemplated and included in the scope of this disclosure. FIGS. 4A-4F are perspective, top, profile, profile, profile, and profile views, respectively, of a semiconductor package having a lead frame based monopole antenna, in accordance with various examples. More specifically, FIGS. 4A-4F depict a semiconductor package 400 that is identical to the semiconductor package 228 of FIGS. 3A-3F, except that the dipole antenna, which includes the members 212a and 212b, is replaced with a monopole antenna 402, which includes members 402a, 402b, and 402c (the members 402a-402c may collectively be referred to herein as a segment). Further, a member 404 replaces the members 208a and 208b. The member 402c extends along a length of the semiconductor die 220. The member 402b extends perpendicular to the member 402a. The member 402a extends parallel to the member 402c and perpendicular to the member 402b. The member 404 is attached to the member 402a. A distal end of the member 404 (relative to a center of the semiconductor package 400) is exposed on the surface 304. The distal end of the member 404 may be exposed on the surface 304 because, during manufacture, the member 404 may have attached to a dam bar extending parallel to the members 402a and 402c and attaching the conductive terminals 202 together. The monopole antenna 402 is soldered to the semiconductor die 220. An integrated circuit on the semiconductor die 220 is capable of operating the monopole antenna 402 by providing signals to and receiving signals from the monopole antenna 402.

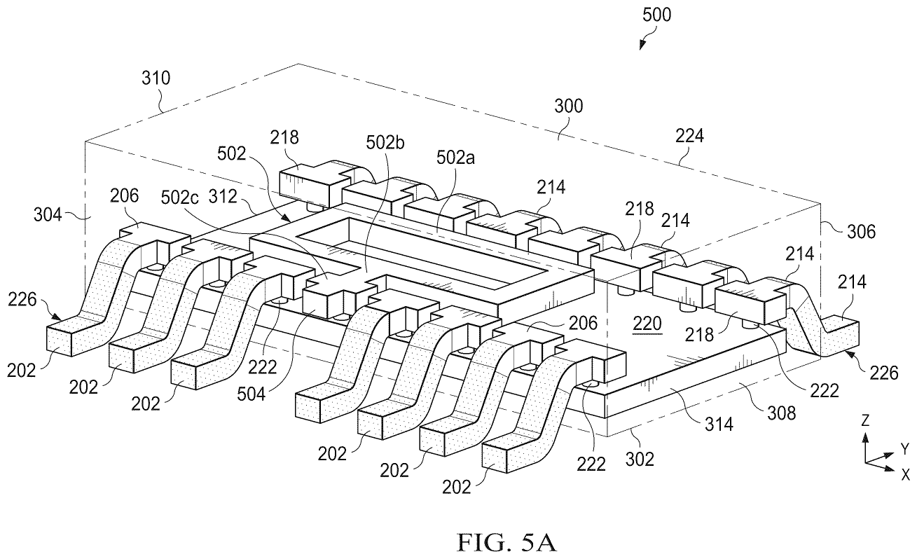

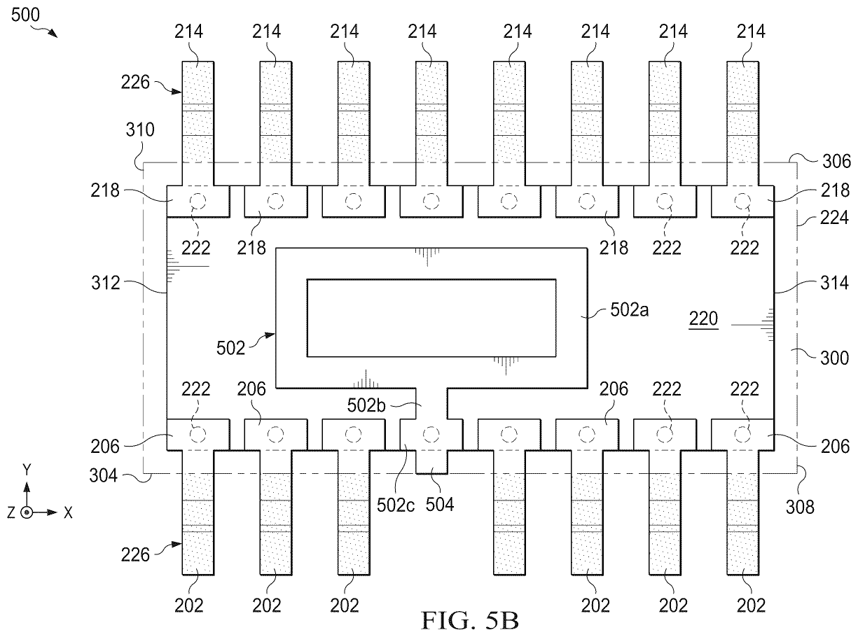

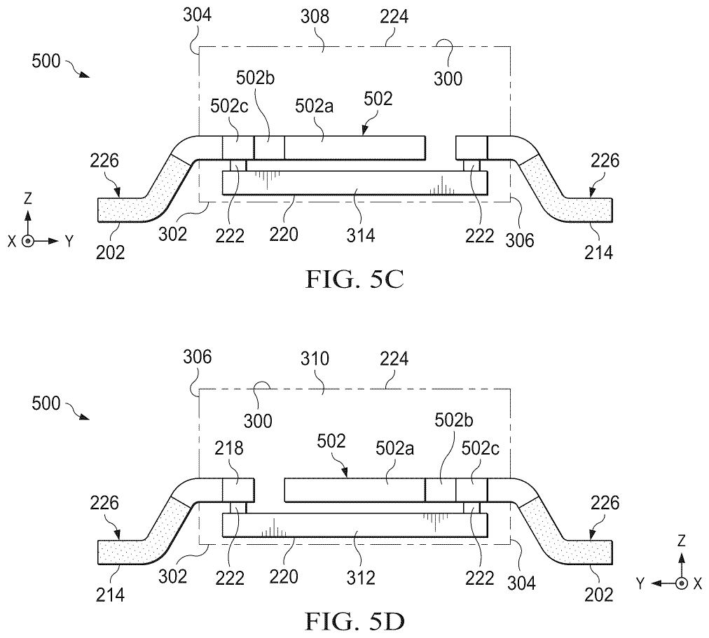

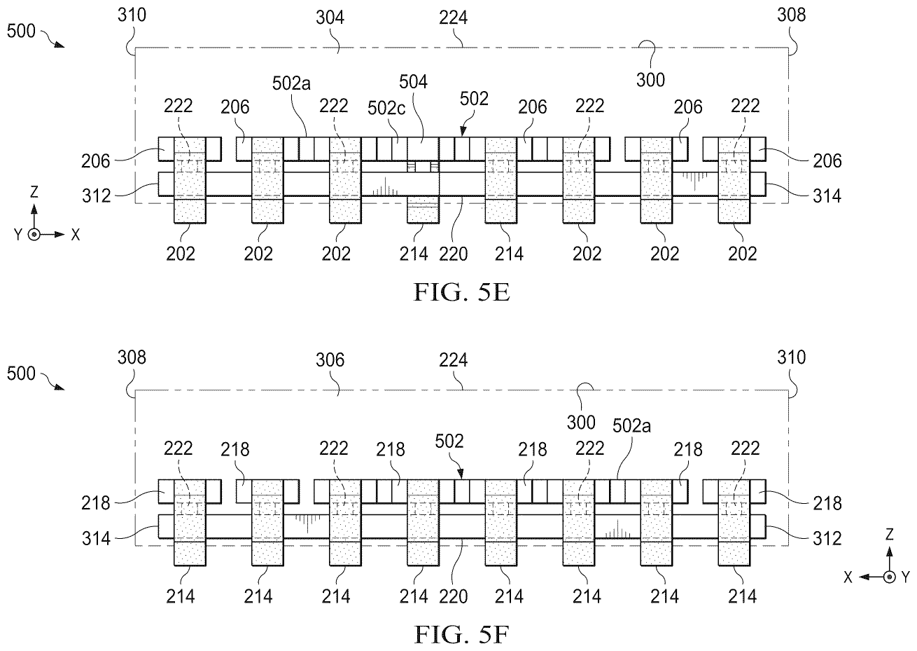

The scope of this disclosure is not limited to semiconductor packages with dipole and monopole antennas. Other types of antennas, such as loop antennas, are contemplated and included in the scope of this disclosure. FIGS. 5A-5F are perspective, top, profile, profile, profile, and profile views, respectively, of a semiconductor package having a lead frame based loop antenna, in accordance with various examples. More specifically, FIGS. 5A-5F depict a semiconductor package 500 that is identical to the semiconductor package 400 of FIGS. 4A-4F, except that a loop antenna 502 replaces the monopole antenna 402. The loop antenna 502 includes a member 502a, a member 502b attached to the member 502a, and a member 502c attached to the member 502b, which collectively may be referred to as a segment. The member 502a comprises a loop (e.g., a rectangular loop, a circular loop), which may be of any suitable size. The member 502c is coupled (e.g., soldered) to the semiconductor die 220, and the member 502b attaches the members 502a and 502c to each other. A member 504 attaches to the member 502c and includes a distal end (relative to a center of the semiconductor package 500) that is exposed on the surface 304. The loop antenna 502 is soldered to the semiconductor die 220. An integrated circuit on the semiconductor die 220 is capable of operating the loop antenna 502 by providing signals to the loop antenna 502 and receiving signals from the loop antenna 502.

As may be the case in FIGS. 2A-2G, components described as being “attached” to each other with reference to FIGS. 3A-3F, 4A-4F, and/or 5A-5F may be parts of a continuous, monolithic whole and may not be attached together using solder or any other type of adhesive.

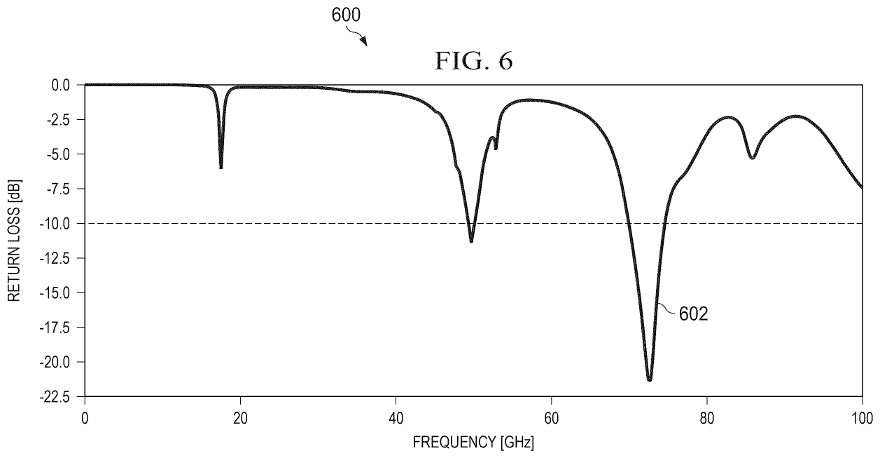

FIG. 6 is a graph 600 depicting the performance of a lead frame based antenna, in accordance with various examples. Although the graph 600 specifically depicts the performance of the dipole antenna of the semiconductor package 228, the behavior shown in the graph 600 is generally indicative of the performance of other lead frame based antennas, such as the monopole antenna in the semiconductor package 400 and the loop antenna in the semiconductor package 500. The graph 600 includes an x-axis depicting frequency in gigahertz (GHz) and a y-axis depicting return loss in decibels (dB). A curve 602 indicates that the antenna operates most efficiently at approximately 72 GHz, where return loss reaches approximately −22 dB, indicating strong impedance matching and minimal reflection. A secondary resonance occurs at approximately 50 GHz with a return loss of approximately −10 dB, indicating acceptable performance. Between approximately 80 and 100 GHz, return loss fluctuates between approximately −2.5 and −7.5 dB, reflecting moderate matching in this higher band. The graph 600 thus indicates that a lead frame based antenna, such as those in the semiconductor packages 228, 400, and 500, provides a low-cost, small-footprint, robust-performance antenna option for a wide range of wireless applications.

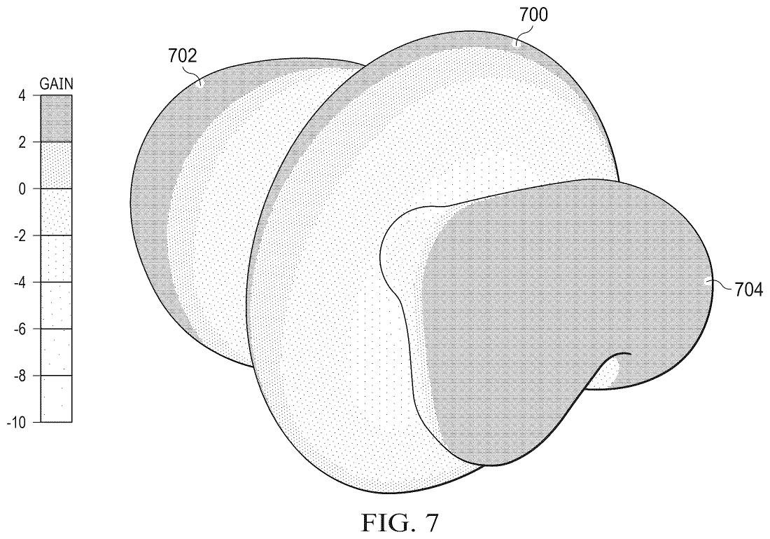

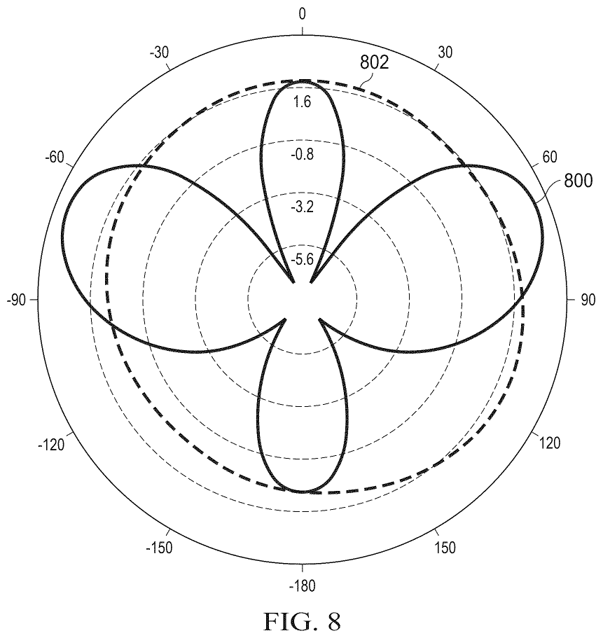

FIGS. 7 and 8 are schematic diagrams showing the radiation patterns produced by a lead frame based antenna, in accordance with various examples. In particular, FIG. 7 shows an example three-dimensional (3D) polar plot indicating the antenna directivity of an example lead frame based antenna, such as a dipole antenna. The 3D polar plot represents antenna directivity using a scale where the maximum gain value is 4 and the minimum gain value is −10. The plot features a vertically oriented central disc 700, having an outer circumference showing higher gain values near 4 and the inner regions displaying lower gain values in the range of approximately 0 to −4. Two lateral lobes 702, 704 extend outward from opposite sides of the central disc. These lobes 702, 704 exhibit higher gain at distal surfaces, corresponding to values near 4, while the proximal regions of the lobes 702, 704 show lower gain values closer to 0 to −4. The spatial distribution of gain indicates the directional characteristics of the lead frame based antenna. FIG. 8 shows a directivity plot for an example lead frame based antenna where Phi=0 degrees (trace 800) and 90 degrees (trace 802). The directivity plot depicts a polar representation of lead frame based antenna performance, with angular positions marked around the perimeter in degrees, beginning at 0 degrees and increasing clockwise through 30, 60, 90, 120, and 150 degrees, reaching −180 degrees at the bottom (in the 6 o'clock position), then continuing clockwise through −150, −120, −90, −60 , −30 degrees, and returning to 0 degrees. Concentric circles within the plot represent gain values, labeled from outer to inner as 1.6, −0.8, −3.2, and −5.6. The closed circular trace 802 approximately follows the 1.6 gain contour, indicating an approximately uniformly distributed component of the radiation pattern. Superimposed on this is the four-lobed, cloverleaf patterned trace 800 with lobes oriented along 0 degrees, −180 degrees, 70 degrees, and −70 degrees. The lobes directed toward 0 and −180 degrees extend vertically, with the upper lobe reaching the 1.6 gain contour and the lower lobe terminating between the 1.6 and −0.8 contours. The lateral lobes oriented toward 70 and −70 degrees extend nearly to the outer boundary of the plot, indicating higher relative gain in those directions. This configuration indicates a directional radiation pattern with dominant lateral lobes and reduced vertical emission symmetry.

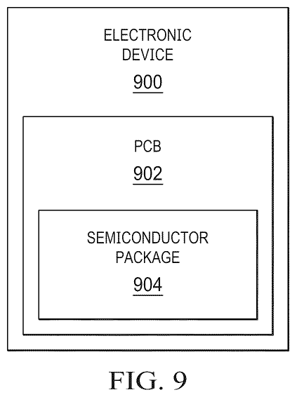

FIG. 9 is a block diagram of an electronic device including a semiconductor package having a lead frame based antenna, in accordance with various examples. Specifically, FIG. 9 shows an electronic device 900, which includes a printed circuit board (PCB) 902 to which a semiconductor package 904 is coupled. The semiconductor package 904 may be representative of any semiconductor package described herein. The electronic device 900 may be of any suitable type, such as a smartphone, a tablet, a laptop computer, a desktop computer, a television, a wireless audio device (e.g., headphones), a video game console, a wireless Internet device, a drone, a sensor, an aircraft, a space craft, a road vehicle, a home appliance, etc. The semiconductor package 904 may have any suitable form, such as an SOT package, a small outline integrated circuit (SOIC) package, a shrink small outline package (SSOP), a thin small outline package (TSOP), a quad flat package (QFP), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a semiconductor die;
a portion of a lead frame, comprising:
conductive terminals coupled to the semiconductor die; and
a first segment having first, second, and third members and a second segment having fourth, fifth, and sixth members, wherein:
the first and fourth members are coupled to the semiconductor die,
the second and fifth members extend from the first and fourth members, respectively, toward a center of the semiconductor die, the second and fifth members extending parallel to each other, and
the third and sixth members extend from the second and fifth members, respectively, in opposing directions perpendicular to the second and fifth members; and
a mold compound contacting the semiconductor die and the portion of the lead frame.

2. The semiconductor package of claim 1, wherein each of the third and sixth members has distal ends exposed on different surfaces of the mold compound.

3. The semiconductor package of claim 1, wherein the first, second, third, fourth, fifth, and sixth members are horizontally coplanar.

4. The semiconductor package of claim 1, wherein the second and fifth members are parallel to the conductive terminals.

5. The semiconductor package of claim 1, further comprising seventh and eighth members extending from the first and fourth members, respectively, away from the center of the semiconductor die, the seventh and eighth members extending parallel to the conductive terminals.

6. The semiconductor package of claim 5, wherein the seventh and eighth members are narrower than the conductive terminals in a top-down view.

7. The semiconductor package of claim 5, wherein the seventh and eighth members include distal ends exposed on a same surface of the mold compound.

8. The semiconductor package of claim 7, wherein the conductive terminals are at least partially covered by a metal coating, and wherein the distal ends of the seventh and eighth members are not covered by the metal coating.

9. The semiconductor package of claim 1, wherein the first and second segments are capable of operating as a dipole antenna.

10. A semiconductor package, comprising:
a semiconductor die; and
a portion of a lead frame, comprising:
conductive terminals having first and second ends, the first ends coupled to the semiconductor die; and
an antenna co-planar with the first ends of the conductive terminals and coupled to the semiconductor die.

11. The semiconductor package of claim 10, wherein the antenna comprises a monopole antenna or a dipole antenna.

12. The semiconductor package of claim 10, wherein the antenna comprises a loop antenna including a loop member and a connection member attached to the loop member, the connection member extending away from a center of the loop member and coupled to the semiconductor die.

13. The semiconductor package of claim 10, wherein the antenna includes first and second segments, each of the first and second segments including first members that couple to the semiconductor die and extend perpendicular to the conductive terminals, second members that attach to the respective first members and extend parallel to the conductive terminals, and third members that attach to the respective second members and extend perpendicular to the conductive terminals.

14. The semiconductor package of claim 13, further comprising a mold compound covering the semiconductor die and the portion of the lead frame, wherein distal ends of the third members are exposed on opposing surfaces of the mold compound.

15. The semiconductor package of claim 14, further comprising fourth members that attach to the respective first members and extend away from a center of the semiconductor die, parallel to the conductive terminals.

16. The semiconductor package of claim 15, wherein the fourth members are exposed on a same surface of the mold compound.

17. The semiconductor package of claim 16, wherein the conductive terminals are at least partially covered by a metal coating, and wherein areas of the fourth members that are exposed on the same surface of the mold compound are not covered by the metal coating.

18. The semiconductor package of claim 15, wherein the fourth members are narrower than the conductive terminals in a top-down view.

19. A method for manufacturing a semiconductor package, comprising:
coupling first and second semiconductor dies to a lead frame strip having first and second lead frames, the first lead frame including a first set of conductive terminals attached to a dam bar, a first member attached to the dam bar and extending lengthwise along the lead frame strip, and a second member attached to the dam bar and extending lengthwise along the lead frame strip in a direction opposite that of the first member, the second lead frame including a second set of conductive terminals attached to the dam bar, the second member, and a third member attached to the dam bar and extending lengthwise along the lead frame strip, the second member shared by the first and second lead frames, wherein the first semiconductor die is coupled to the first set of conductive terminals, the first member, and the second member, and wherein the second semiconductor die is coupled to the second set of conductive terminals, the second member, and the third member;
covering the first and second semiconductor dies and the lead frame strip with a mold compound; and
sawing the mold compound, wherein the semiconductor package includes the first semiconductor die, the first set of conductive terminals, the first member, and a portion of the second member.

20. The method of claim 19, wherein the first and second members have distal ends exposed on different surfaces of the mold compound.
